(19) United States
(12) Patent Application Publication
(10) Pub. No.: US 2026/0039305 A1
(43) Pub. Date: Feb. 5, 2026

(54) METHODS AND APPARATUS TO REDUCE ACCUMULATION IN ANALOG-TO-DIGITAL CONVERTERS

(71) Applicant: Texas Instruments Incorporated, Dallas, TX (US)

(72) Inventor: Eeshan Miglani, Bangalore (IN)

(21) Appl. No.: 18/790,598

(22) Filed: Jul. 31, 2024

(51) Int. Cl. H03M 1/06

(52) U.S. Cl. CPC H03M 1/0604

(57) ABSTRACT

An example apparatus includes: combination circuitry having a first input, a second input, and an output; analog-to-digital converter (ADC) circuitry having an input and an output, the input of the ADC circuitry coupled to the output of the combination circuitry; digital-to-analog converter (DAC) circuitry having an input and an output, the input of the DAC coupled to the output of the ADC circuitry; a resistor having a first terminal and a second terminal, the first terminal of the resistor coupled to the first input of the combination circuitry; amplifier circuitry having an input coupled to the output of the DAC circuitry and the second terminal of the resistor.

### TECHNICAL FIELD

This description relates generally to analog-to-digital conversions and, more particularly, to methods and apparatus to reduce accumulation in analog-to-digital converters.

### BACKGROUND

As electronics continue to advance, systems have become capable of safely operating at increasingly complex operating conditions, such as higher speeds and higher accuracies. In analog-to-digital converter (ADC) circuitry, increasingly complex circuitry implements advanced techniques to support increasing conversion speeds and higher resolution outputs. Such circuitry allows ADC circuitry to precisely generate outputs at higher resolutions despite complex operating conditions.

### SUMMARY

For methods and apparatus to reduce accumulation in analog-to-digital converters, an example apparatus includes combination circuitry having a first input, a second input, and an output; analog-to-digital converter (ADC) circuitry having an input and an output, the input of the ADC circuitry coupled to the output of the combination circuitry; digital-to-analog converter (DAC) circuitry having an input and an output, the input of the DAC coupled to the output of the ADC circuitry; a resistor having a first terminal and a second terminal, the first terminal of the resistor coupled to the first input of the combination circuitry; amplifier circuitry having an input coupled to the output of the DAC circuitry and the second terminal of the resistor. Other examples are described.

For methods and apparatus to reduce accumulation in analog-to-digital converters, an example apparatus includes combination circuitry having an input and an output; analog-to-digital converter (ADC) circuitry having an input and an output, the input of the ADC circuitry coupled to the output of the combination circuitry; digital-to-analog converter (DAC) circuitry having an input and an output, the input of the DAC coupled to the output of the ADC circuitry; first amplifier circuitry having an input and an output, the input of the first amplifier circuitry coupled to the output of the DAC circuitry; and second amplifier circuitry having an input and an output, the input of the second amplifier circuitry coupled to the output of the first amplifier circuitry, the output of the second amplifier circuitry coupled to the input of the combination circuitry. Other examples are described.

For methods and apparatus to reduce accumulation in analog-to-digital converters, an example apparatus includes combination circuitry having an input and an output; analog-to-digital converter (ADC) circuitry having an input, a first output, and a second output, the input of the ADC circuitry coupled to the output of the combination circuitry; first digital-to-analog converter (DAC) circuitry having an input and an output, the input of the first DAC coupled to the first output of the ADC circuitry; amplifier circuitry having an input coupled to the output of the DAC circuitry; and second DAC circuitry having an input and an output, the input of the second DAC coupled to the second output of the ADC circuitry, the output of the second DAC coupled to the input of the combination circuitry. Other examples are described.

For methods and apparatus to reduce accumulation in analog-to-digital converters, an example apparatus includes an first inter-stage gain circuitry including: combination circuitry having an input and an output; analog-to-digital converter (ADC) circuitry having an input and an output, the input of the ADC circuitry coupled to the output of the combination circuitry; digital-to-analog converter (DAC) circuitry having an input and an output, the input of the DAC coupled to the output of the ADC circuitry; and amplifier circuitry having an input and an output, the input of the amplifier circuitry coupled to the output of the DAC circuitry; and second inter-stage gain circuitry having an input coupled to the output of the amplifier circuitry. Other examples are described.

### BRIEF DESCRIPTION OF THE DRAWINGS

FIG. 1 is a block diagram of an example continuous time pipeline ADC including example inter-stage gain circuitry.

FIG. 2 is a schematic diagram of an example of the inter-stage gain circuitry of FIG. 1 including example feedback circuitry.

FIG. 3 is a schematic diagram of another example of the inter-stage gain circuitry of FIGS. 1 and 2 including the feedback circuitry of FIG. 2.

FIG. 4 is a schematic diagram of another example of the inter-stage gain circuitry of FIGS. 1, 2, and 3 including example feedback circuitry of FIGS. 2 and 3.

FIG. 5 is a flowchart representative of example operations that may be at least one of executed, instantiated, or performed using an example implementation of inter-stage gain circuitry of FIGS. 1, 2, and 3.

FIG. 6 is a schematic diagram of an example of the inter-stage gain circuitry of FIG. 1 including example feedback circuitry.

FIG. 7 is a schematic diagram of another example of the inter-stage gain circuitry of FIGS. 1 and 6 including another example of the feedback circuitry of FIG. 6.

FIG. 8 is a flowchart representative of example operations that may be at least one of executed, instantiated, or performed using an example implementation of inter-stage gain circuitry of FIGS. 1, 6, and 7 using the feedback circuitry of FIGS. 6 and 7.

FIG. 9 is a timing diagram of example operations of the inter-stage gain circuitry of FIGS. 1, 2, 3, 6, and 7 including the feedback circuitry of FIGS. 2, 3, 6, and 7.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

As electronics continue to advance, systems have become capable of safely operating at increasingly complex operating conditions, such as higher speeds and higher accuracies. In analog-to-digital converter (ADC) circuitry, increasingly complex circuitry implements advanced techniques to support increasing conversion speeds and higher resolution outputs. Such circuitry allows ADC circuitry to precisely generate outputs at higher resolutions despite complex operating conditions.

In some designs, ADC circuitry needs to convert analog values to digital bits at relatively high speeds to accurately represent an analog input signal. Continuous time pipeline (CTP) ADC circuitry uses a plurality of stages coupled in series to convert an analog value to digital bits. Each stage of the CTP ADC corresponds to a resolution of a digital output. For example, a first stage of the CTP ADC produces one or more of the most significant bits of the digital output, the second stage, which follows the first stage, produces one or more of the next most significant bits after the output of the first stage. Each stage includes inter-stage gain circuitry and one or more latches. The one or more latches of each stage sequence a supply of the one or more bits from the inter-stage gain circuitry to an output latch, which supplies the digital output as a combination of bits from each stage.

Each instance of the inter-stage gain circuitry is either coupled to circuitry that supplies an analog input signal or an output of a previous instance of the inter-stage gain circuitry. The inter-stage gain circuitry includes delay circuitry, sub-ADC circuitry, digital-to-analog converter (DAC) circuitry, amplifier circuitry, and filter circuitry. The sub-ADC circuitry samples the analog input signal to determine an analog input voltage to convert to digital. The sub-ADC circuitry performs a relatively low-resolution analog-to-digital conversion of the analog input voltage in comparison to the resolution of the output of the CTP ADC circuitry. The sub-ADC circuitry supplies one or more bits from the relatively low-resolution conversion to the DAC circuitry and a latch. The latch supplies the one or more bits to the output latch of the CTP ADC circuitry.

The DAC circuitry generates an approximation of the analog input voltage using the one or more bits. The delay circuitry delays the analog input signal by a delay duration, which gives the sub-ADC circuitry and the DAC circuitry time to convert the analog input voltage. The amplifier circuitry generates an output voltage that is proportional to the difference between the approximation of the analog input voltage and the actual analog input voltage. Such a difference is referred to as a residue or quantization error. The amplifier circuitry amplifies the residue by a gain and supplies the amplified residue to a subsequent instance of the inter-stage gain circuitry. The subsequent instance of the inter-stage gain circuitry uses the amplified residue to determine higher resolution bits.

The filter circuitry is coupled between an input and output of the amplifier circuitry. The filter circuitry provides a feedback path for current from the output of the amplifier circuitry. The filter circuitry stabilizes the inter-stage gain circuitry by reducing the response time of the amplifier circuitry to voltages at the input. The filter circuitry also removes high-frequency noise from the output of the amplifier circuitry. However, capacitive and inductive components of the filter circuitry accumulate charge from residues of previous samples. Such accumulation impacts the signal to noise ratio (SNR) of the CTP ADC circuitry. Further, the accumulation impacts the accuracy of subsequent instances of the inter-stage gain circuitry. Increasing the resolution of the sub-ADC circuitry and the DAC circuitry reduces accumulation by decreasing the residue. However, increasing the resolution of the sub-ADC circuitry and the DAC circuitry increases the conversion time for each stage of the CTP ADC and increases power consumption.

Examples described herein include methods and apparatus to reduce accumulation in ADCs using feedback circuitry to compensate analog inputs for residues. In some described examples, inter-stage gain circuitry includes combination circuitry and feedback circuitry between the input of the inter-stage gain circuitry and the sub-ADC circuitry. The combination circuitry compensates the analog input signal for residue accumulation using voltages from the feedback circuitry. In some examples, the feedback circuitry is amplifier circuitry coupled to the combination circuitry and the output of the inter-stage gain circuitry. In such examples, the amplifier circuitry multiplies the voltage at the output of the inter-stage gain circuitry by a feedback gain to generate a compensation voltage that is proportional to the residue. Also, the feedback gain may be determined using a transfer function.

In other examples, the feedback circuitry is additional DAC circuitry coupled to the sub-ADC circuitry and the combination circuitry. The additional DAC circuitry receives the least significant bits of the output of the sub-ADC circuitry. The DAC circuitry generates an analog error voltage using the least significant bits. The combination circuitry adds the analog error voltage to the analog input signal to compensate for accumulation of the previous residue. Advantageously, the combination circuitry and the feedback circuitry compensate the analog input signal for accumulation of previous residues in the filter circuitry. Advantageously, the combination circuitry and the feedback circuitry improve the sound to noise ratio of the CTP ADC circuitry.

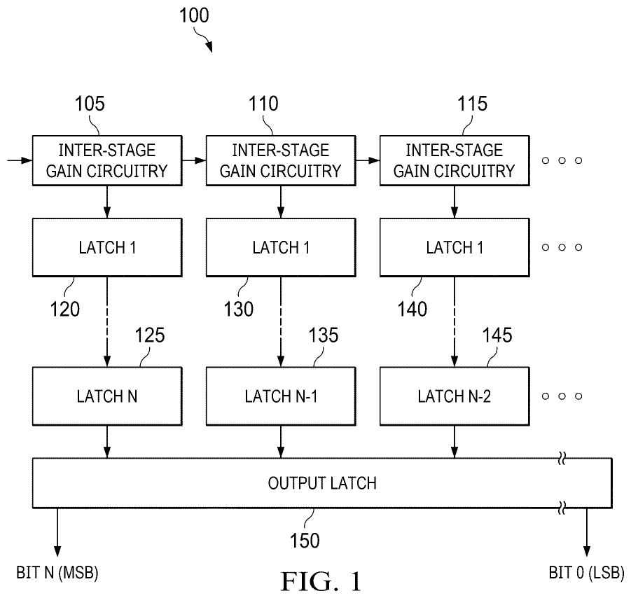

FIG. 1 is a block diagram of example continuous time pipeline (CTP) ADC circuitry 100. In the example of FIG. 1, the CTP ADC circuitry 100 includes first inter-stage gain circuitry 105, second inter-stage gain circuitry 110, third inter-stage gain circuitry 115, a first latch 120, a second latch 125, a third latch 130, a fourth latch 135, a fifth latch 140, a sixth latch 145, and a seventh latch 150. The CTP ADC circuitry 100 has an input terminal and output terminals. The input terminal of the CTP ADC circuitry 100 is structured to be coupled to external circuitry, which supplies an analog input signal. The output terminals of the CTP ADC circuitry 100 are structured to be coupled to external circuitry, which receives a digital output signal. In some examples, the CTP ADC circuitry 100 receives the analog input signal from a sensor, analog device, instrumentation system, imaging system, etc. In some such examples, the CTP ADC circuitry 100 supplies the digital output signal to programmable circuitry, such as a processing unit, signal processing circuitry, etc.

The inter-stage gain circuitry 105 has an input terminal, a first output terminal, and a second output terminal. The input terminal of the inter-stage gain circuitry 105 is coupled to the input terminal of the CTP ADC circuitry 100, which supplies the analog input signal. The first output terminal of the inter-stage gain circuitry 105 is coupled to the inter-stage gain circuitry 110. The second output terminal of the inter-stage gain circuitry 105 is coupled to the latch 120. The inter-stage gain circuitry 110 has an input terminal, a first output terminal, and a second output terminal. The input terminal of the inter-stage gain circuitry 110 is coupled to the inter-stage gain circuitry 105. The first output terminal of the inter-stage gain circuitry 110 is coupled to the inter-stage gain circuitry 115. The second output terminal of the inter-stage gain circuitry 110 is coupled to the latch 130. The inter-stage gain circuitry 115 has an input terminal, a first output terminal, and a second output terminal. The input terminal of the inter-stage gain circuitry 115 is coupled to the inter-stage gain circuitry 110. The first output terminal of the inter-stage gain circuitry 115 may be coupled to additional instances of the inter-stage gain circuitry 105, 110, 115. In some examples, the additional instances of the inter-stage gain circuitry 105, 110, 115 increase the resolution of the CTP ADC circuitry 100. The second output terminal of the inter-stage gain circuitry 115 is coupled to the latch 140.

The latch 120 has an input terminal and an output terminal. The input terminal of the latch 120 is coupled to the inter-stage gain circuitry 105. The output terminal of the latch 120 is coupled to the latch 125. The latch 125 has an input terminal and an output terminal. The input terminal of the latch 125 is coupled to the latch 120. The output terminal of the latch 125 is coupled to the latch 150. In some examples, the CTP ADC circuitry 100 includes one or more additional latches coupled between the latches 120, 125. In such examples, the number of additional latches corresponds to the number of additional ones of the inter-stage gain circuitry 105, 110, 115 following the inter-stage gain circuitry 105.

The latch 130 has an input terminal and an output terminal. The input terminal of the latch 130 is coupled to the inter-stage gain circuitry 110. The output terminal of the latch 130 is coupled to the latch 135. The latch 135 has an input terminal and an output terminal. The input terminal of the latch 135 is coupled to the latch 130. The output terminal of the latch 135 is coupled to the latch 150. In some examples, the CTP ADC circuitry 100 includes one or more additional latches coupled between the latches 130, 135. In such examples, the number of additional latches corresponds to the number of additional ones of the inter-stage gain circuitry 105, 110, 115 following the inter-stage gain circuitry 110.

The latch 140 has an input terminal and an output terminal. The input terminal of the latch 140 is coupled to the inter-stage gain circuitry 115. The output terminal of the latch 140 is coupled to the latch 145. The latch 145 has an input terminal and an output terminal. The input terminal of the latch 145 is coupled to the latch 140. The output terminal of the latch 145 is coupled to the latch 150. In some examples, the CTP ADC circuitry 100 includes one or more additional latches coupled between the latches 140, 145 or one or more less latches coupled between the inter-stage gain circuitry 115 and the latch 150. In such examples, the number of latches corresponds to the number of additional ones of the inter-stage gain circuitry 105, 110, 115 following the inter-stage gain circuitry 115.

The latch 150 (also referred to as an output latch) has input terminals and output terminals. The input terminals of the latch 150 are coupled to the latches 125, 135, 145. The output terminals of the latch 150 are coupled to the output terminals of the CTP ADC circuitry 100, which supply the digital output signal to external circuitry.

In example operation, the inter-stage gain circuitry 105 receives the analog input signal at the input terminal of the CTP ADC circuitry 100. The inter-stage gain circuitry 105 determines an analog value to convert by sampling the analog input signal at a first time. The inter-stage gain circuitry 105 generates one or more digital bits that represent the sampled analog value at a first resolution. The latch 120 latches the one or more digital bits. The inter-stage gain circuitry 105 amplifies the difference between the sampled analog value and an analog representation of the one or more digital bits.

In such example operations, the inter-stage gain circuitry 110 generates one or more digital bits that represent the amplified difference of the analog value at a second time. Also at the second time, the latch 125 latches the digital bits of the latch 120 and the latch 130 latches the one or more digital bits from the inter-stage gain circuitry 110. The inter-stage gain circuitry 110 amplifies the difference between the remaining portions of the sampled analog value and an analog representation of the one or more digital bits.

In such example operations, the inter-stage gain circuitry 115 generates one or more digital bits that represent the amplified difference of the analog value at a third time. Also at the third time, the latch 135 latches the digital bits of the latch 130 and the latch 140 latches the one or more digital bits from the inter-stage gain circuitry 115. At the third time, the digital bits of the latches 125, 135, 140 form a digital representation of the sampled analog value. At a fourth time, the latch 150 supplies the determined digital bits to external circuitry. Also, during the second and third times, the inter-stage gain circuitry 105, 110 proceed to sample and convert subsequent analog values of the analog input signal.

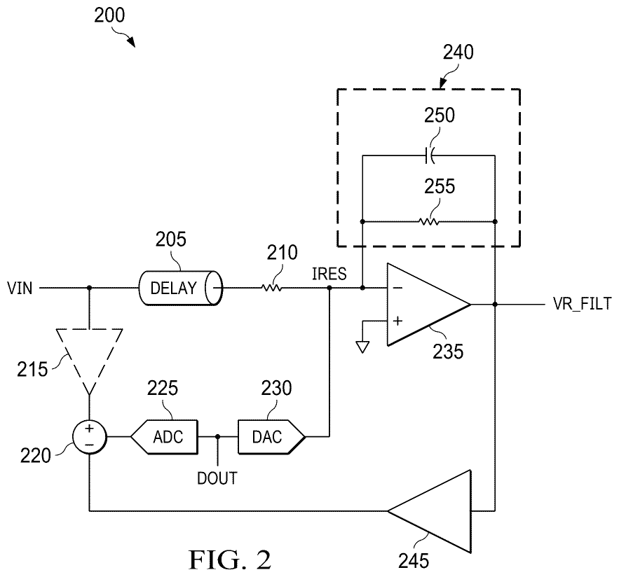

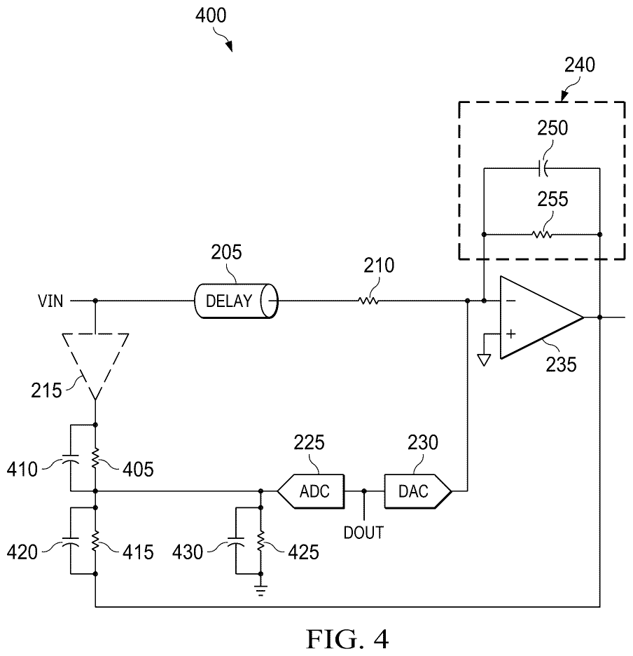

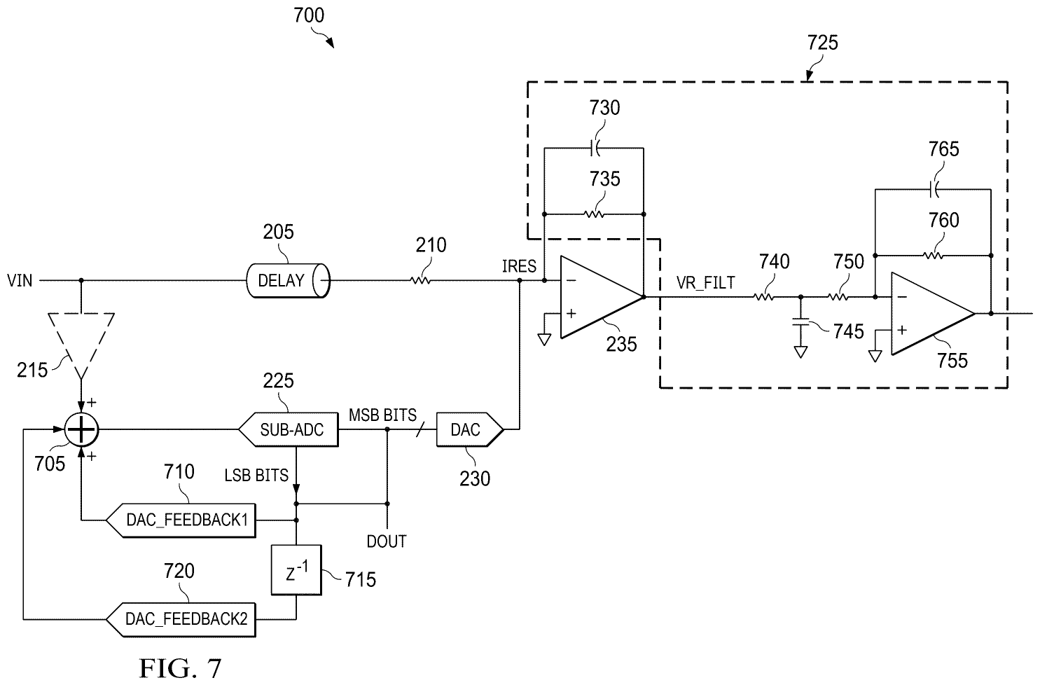

Examples of the inter-stage gain circuitry 105, 110, 115 are illustrated and described in connection with FIGS. 2, 3, 5, and 6. Example operations of the inter-stage gain circuitry 105, 110, 115 are further illustrated and described in connection with FIGS. 4 and 7.

FIG. 2 is a schematic diagram of example inter-stage gain circuitry 200, which is an example of the inter-stage gain circuitry 105, 110, 115 of FIG. 1. In the example of FIG. 2, the inter-stage gain circuitry 200 includes delay circuitry 205, a first resistor 210, interconnect circuitry 215, combination circuitry 220, ADC circuitry 225, DAC circuitry 230, first amplifier circuitry 235, filter circuitry 240, and second amplifier circuitry 245. The example filter circuitry 240 of FIG. 2 includes an example capacitor 250 and a second example resistor 255.

The inter-stage gain circuitry 200 has an input terminal, a first output terminal, and a second output terminal. The input terminal of the inter-stage gain circuitry 200 is structured to be coupled to one of an output terminal of a prior instance of the inter-stage gain circuitry 200 or external circuitry, which supplies an analog input signal (Vin). In both examples, the inter-stage gain circuitry 200 receives the analog input signal at the input terminal. The first output terminal of the inter-stage gain circuitry 200 is structured to be coupled to a subsequent instance of the inter-stage gain circuitry 200. The second output terminal of the inter-stage gain circuitry 200 is structured to be coupled to a latch (e.g., the latches 120, 130, 140 of FIG. 1). In some examples, the inter-stage gain circuitry 200 has a plurality of output terminals that are structured to supply a plurality of digital bits (DOUT) to a latch or external circuitry.

The delay circuitry 205 has a first terminal and a second terminal. The first terminal of the delay circuitry 205 is coupled to the interconnect circuitry 215 and the input terminal of the inter-stage gain circuitry 200, which supplies the analog input signal. The second terminal of the delay circuitry 205 is coupled to the resistor 210. In some examples, the delay circuitry 205 is a discrete component structured to delay propagation of the analog input signal. In other examples, the delay circuitry 205 is a passive component, such as an electrical trace, which reduces a speed of the propagation of the analog input signal.

The resistor 210 has a first terminal and a second terminal. The first terminal of the resistor 210 is coupled to the delay circuitry 205. The second terminal of the resistor 210 is coupled to the DAC circuitry 230, the amplifier circuitry 235, and the filter circuitry 240. In the example of FIG. 2, the resistor 210 is structured to isolate voltages of the amplifier circuitry 235 from voltages of the analog input signal. In the example of FIG. 2, the resistor 210 is illustrated and described as a discrete component separate from the delay circuitry 205. Alternatively, in some examples, such as when the delay circuitry 205 is a transmission line, the resistor 210 may be illustrated or described as a part of the delay circuitry 205. For example, the resistor 210 may be illustrated or described as an equivalent resistance of a component of the delay circuitry 205.

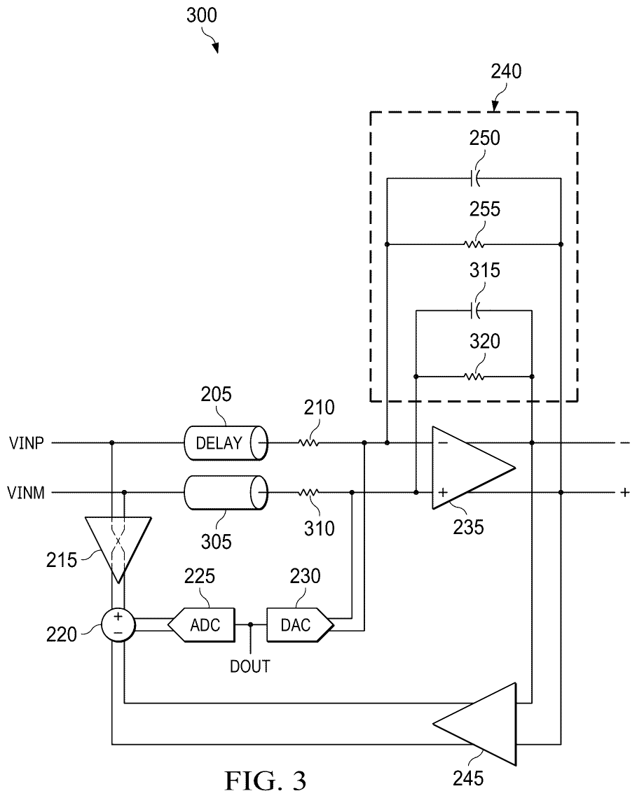

The interconnect circuitry 215 has a first terminal and a second terminal. The first terminal of the interconnect circuitry 215 is coupled to the delay circuitry 205 and the input terminal of the inter-stage gain circuitry 200, which supplies the analog input signal. The second terminal of the interconnect circuitry 215 is coupled to the combination circuitry 220. In some examples, the inter-stage gain circuitry 200 may be illustrated and described without the interconnect circuitry 215. For example, when the inter-stage gain circuitry 200 is structured for single-ended signals, as shown in FIG. 2, the interconnect circuitry 215 may be removed. In such examples, the combination circuitry 220 is directly coupled to the input terminal of the inter-stage gain circuitry 200 and the delay circuitry 205. However, when the inter-stage gain circuitry 200 is structured for differential signals, as shown in FIG. 3, the interconnect circuitry 215 is included. The interconnect circuitry 215 is circuitry structured to swap p-side and m-side signals. The interconnect circuitry 215 is further described and illustrated in connection with FIG. 3, below.

The combination circuitry 220 has a first terminal, a second terminal, and a third terminal. The first terminal of the combination circuitry 220 (also referred to as a first input terminal) is coupled to the interconnect circuitry 215. The second terminal of the combination circuitry 220 (also referred to as a second input terminal) is coupled to the amplifier circuitry 245. The third terminal of the combination circuitry 220 (also referred to as an output terminal) is coupled to the ADC circuitry 225. In the example of FIG. 2, the combination circuitry 220 is structured as subtraction circuitry, which subtracts the second input from the first input.

The ADC circuitry 225 has an input terminal and output terminals. The input terminal of the ADC circuitry 225 is coupled to the combination circuitry 220. The output terminals of the ADC circuitry 225 are coupled to the DAC circuitry 230 and the output terminal(s) of the inter-stage gain circuitry 200. In some examples, the ADC circuitry 225 is illustrated and described as flash memory, which is structured for analog-to-digital conversions. Also, one or more output terminals of the ADC circuitry 225 may be separately coupled to one of the DAC circuitry 230 or the output terminal(s) of the inter-stage gain circuitry 200. For example, the output terminal of the inter-stage gain circuitry 200 may be coupled to the most significant bit of an output of the ADC circuitry 225.

The DAC circuitry 230 has input terminals and an output terminal. The input terminals of the DAC circuitry 230 are coupled to the ADC circuitry 225 and may be coupled to the output terminal(s) of the inter-stage gain circuitry 200. The output terminal of the DAC circuitry 230 is coupled to the resistor 210, the amplifier circuitry 235, and the filter circuitry 240.

The amplifier circuitry 235 has a first input terminal, a second input terminal, and an output terminal. The first input terminal of the amplifier circuitry 235 (also referred to as a non-inverting input terminal) is coupled to the resistor 210, the DAC circuitry 230, and the filter circuitry 240. The second input terminal of the amplifier circuitry 235 (also referred to as an inverting input terminal) is coupled to a common terminal, which supplies a common potential (e.g., ground, AVSS, etc.). The output terminal of the amplifier circuitry 235 is coupled to the filter circuitry 240, the amplifier circuitry 245, and the first output terminal of the inter-stage gain circuitry 200, which may be coupled to another instance of the inter-stage gain circuitry 200.

The filter circuitry 240 has a first terminal and a second terminal. The first terminal of the filter circuitry 240 is coupled to the resistor 210, the DAC circuitry 230, and the amplifier circuitry 235. The second terminal of the filter circuitry 240 is coupled to the amplifier circuitry 235, 245 and the first output terminal of the inter-stage gain circuitry 200, which may be coupled to another instance of the inter-stage gain circuitry 200.

The amplifier circuitry 245 (also referred to as feedback circuitry) has an input terminal and an output terminal. The input terminal of the amplifier circuitry 245 is coupled to the amplifier circuitry 235 and the first output terminal of the inter-stage gain circuitry 200, which may be coupled to another instance of the inter-stage gain circuitry 200. The output terminal of the amplifier circuitry 245 is coupled to the combination circuitry 220.

The capacitor 250 has a first terminal and a second terminal. The first terminal of the capacitor 250 is coupled to the resistor 210, the DAC circuitry 230, the amplifier circuitry 235, and the resistor 255. The second terminal of the capacitor 250 is coupled to the amplifier circuitry 235, 245, the resistor 255, and the first output terminal of the inter-stage gain circuitry 200, which may be coupled to another instance of the inter-stage gain circuitry 200. The resistor 255 has a first terminal and a second terminal. The first terminal of the resistor 255 is coupled to the resistor 210, the DAC circuitry 230, the amplifier circuitry 235, and the capacitor 250. The second terminal of the resistor 255 is coupled to the amplifier circuitry 235, 245, the capacitor 250, and the first output terminal of the inter-stage gain circuitry 200, which may be coupled to another instance of the inter-stage gain circuitry 200. In the example of FIG. 2, the capacitor 250 and the resistor 255 form low-pass filter circuitry. Alternatively, the capacitor 250 and the resistor 255 may be replaced with alternative circuitry to form another low pass filter or another type of filter.

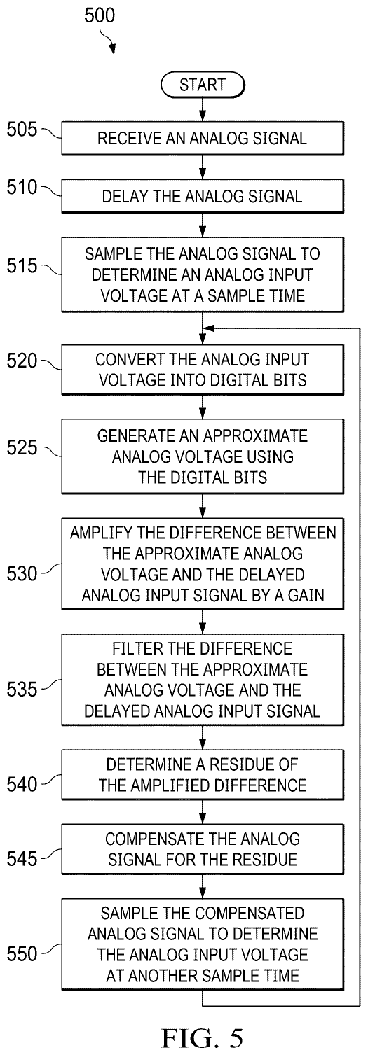

Example operations of the inter-stage gain circuitry 200 are illustrated and described in connection with FIG. 5, below. Advantageously, the combination circuitry 220 and the amplifier circuitry 245 form a feedback path to compensate the analog input signal for accumulation of the filter circuitry 240. Advantageously, compensating the analog input signal for accumulation increases the signal to noise ratio.

FIG. 3 is a schematic diagram of example inter-stage gain circuitry 300, which is another example of the inter-stage gain circuitry 105, 110, 115, 200 of FIGS. 1 and 2. In the example of FIG. 3, the inter-stage gain circuitry 300 includes the delay circuitry 205 of FIG. 2, the resistor 210 of FIG. 2, the interconnect circuitry 215 of FIG. 2, the combination circuitry 220 of FIG. 2, the ADC circuitry 225 of FIG. 2, the DAC circuitry 230 of FIG. 2, the amplifier circuitry 235 of FIG. 2, the filter circuitry 240 of FIG. 2, the amplifier circuitry 245 of FIG. 2, second delay circuitry 305, and a third resistor 310. The example filter circuitry 240 of FIG. 3 includes the capacitor 250 of FIG. 2, the resistor 255 of FIG. 2, a second capacitor 315, and a fourth resistor 320. In the example of FIG. 3, the inter-stage gain circuitry 300 is a fully differential representation of the inter-stage gain circuitry 200.

The inter-stage gain circuitry 300 has a first input terminal, a second input terminal, first output terminals, and second output terminals. The first input terminal of the inter-stage gain circuitry 300 is structured to be coupled to one of an output terminal of a prior instance of the inter-stage gain circuitry 300 or external circuitry, which supplies a p-side analog input signal (Vinp). The second input terminal of the inter-stage gain circuitry 300 is structured to be coupled to the one of an output terminal of a prior instance of the inter-stage gain circuitry 300 or external circuitry, which supplies a m-side analog input signal (Vinm). In the example of FIG. 3, the difference between the p-side and m-side analog input signals represent the analog input signal. The first output terminals of the inter-stage gain circuitry 300 are structured to be coupled to a subsequent instance of the inter-stage gain circuitry 300. The second output terminals of the inter-stage gain circuitry 300 are structured to be coupled to a latch (e.g., the latches 120, 130, 140 of FIG. 1).

The delay circuitry 305 has a first terminal and a second terminal. The first terminal of the delay circuitry 305 is coupled to the interconnect circuitry 215 and the second input terminal of the inter-stage gain circuitry 300, which supplies the p-side analog input signal. The second terminal of the delay circuitry 305 is coupled to the resistor 310. In some examples, the delay circuitry 305 is a discrete component structured to delay propagation of the analog input signal. In other examples, the delay circuitry 305 is a passive component, such as an electrical trace, which reduces a speed of the propagation of the analog input signal.

The resistor 310 has a first terminal and a second terminal. The first terminal of the resistor 310 is coupled to the delay circuitry 305. The second terminal of the resistor 310 is coupled to the DAC circuitry 230, the amplifier circuitry 235, and the filter circuitry 240. In the example of FIG. 3, the resistor 310 is structured to isolate voltages of the amplifier circuitry 235 from voltages of the analog input signal.

The capacitor 315 has a first terminal and a second terminal. The first terminal of the capacitor 315 is coupled to the DAC circuitry 230, the amplifier circuitry 235, and the resistors 310, 320. The second terminal of the capacitor 315 is coupled to the amplifier circuitry 235, 245, the resistor 320, and one of the first output terminals of the inter-stage gain circuitry 300, which may be coupled to another instance of the inter-stage gain circuitry 300. The resistor 320 has a first terminal and a second terminal. The first terminal of the resistor 255 is coupled to the DAC circuitry 230, the amplifier circuitry 235, the resistor 310, and the capacitor 315. The second terminal of the resistor 320 is coupled to the amplifier circuitry 235, 245, the capacitor 315, and the first one of the first output terminals of the inter-stage gain circuitry 300, which may be coupled to another instance of the inter-stage gain circuitry 300. In the example of FIG. 3, the capacitor 315 and the resistor 320 form low-pass filter circuitry. Alternatively, the capacitor 315 and the resistor 320 may be replaced with alternative circuitry to form another low pass filter or another type of filter.

In the example of FIG. 3, the interconnect circuitry 215 switches the p-side and m-side analog input signals. Alternatively, the inter-stage gain circuitry 300 may be modified to remove or replace the interconnect circuitry 215 with alternative circuitry. Example operations of the inter-stage gain circuitry 300 are illustrated and described in connection with FIG. 5. Advantageously, the combination circuitry 220 and the amplifier circuitry 245 are capable of compensating differential signals for accumulation.

FIG. 4 is a schematic diagram of example inter-stage gain circuitry 400, which is another example of the inter-stage gain circuitry 105, 110, 115, 200, 300 of FIGS. 1, 2, and 3. In the example of FIG. 4, the inter-stage gain circuitry 400 includes the delay circuitry 205 of FIGS. 2 and 3, the resistor 210 of FIGS. 2 and 3, the interconnect circuitry 215 of FIGS. 2 and 3, the ADC circuitry 225 of FIGS. 2 and 3, the DAC circuitry 230 FIGS. 2 and 3, the amplifier circuitry 235 of FIGS. 2 and 3, the filter circuitry 240 of FIGS. 2 and 3, a first example resistor 405, a first example capacitor 410, a second example resistor 415, a second example capacitor 420, a third example resistor 425, and a third example capacitor 430. The example filter circuitry 240 of FIG. 4 includes the capacitor 250 of FIGS. 2 and 3 and the resistor 255 of FIGS. 2 and 3.

The resistor 405 has a first terminal and a second terminal. The first terminal of the resistor 405 is coupled to the interconnect circuitry 215 and the capacitor 410. The second terminal of the resistor 405 is coupled to the ADC circuitry 225, the capacitors 410, 420, 430, and the resistors 415, 425.

The capacitor 410 has a first terminal and a second terminal. The first terminal of the capacitor 410 is coupled to the interconnect circuitry 215 and the resistor 405. The second terminal of the capacitor 410 is coupled to the ADC circuitry 225, the resistors 405, 415, 425, and the capacitors 420, 430.

The resistor 415 has a first terminal and a second terminal. The first terminal of the resistor 415 is coupled to the ADC circuitry 225, the resistors 405, 425, and the capacitors 410, 420, 430. The second terminal of the resistor 415 is coupled to the amplifier circuitry 235, the filter circuitry 240, and the capacitor 420.

The capacitor 420 has a first terminal and a second terminal. The first terminal of the capacitor 420 is coupled to the ADC circuitry 225, the resistors 405, 415, 425, and the capacitors 410, 430. The second terminal of the capacitor 420 is coupled to the amplifier circuitry 235, the filter circuitry 240, and the resistor 415.

The resistor 425 has a first terminal and a second terminal. The first terminal of the resistor 425 is coupled to the ADC circuitry 225, the resistors 405, 415, and the capacitors 410, 420, 430. The second terminal of the resistor 425 is coupled to the common terminal, which supplies the common potential.

The capacitor 430 has a first terminal and a second terminal. The first terminal of the capacitor 430 is coupled to the ADC circuitry 225, the resistors 405, 415, 425, and the capacitors 410, 420. The second terminal of the capacitor 430 is coupled to the common terminal, which supplies the common potential.

In the example of FIG. 4, the resistors 405, 415, 425 and the capacitors 410, 420, 430 have resistances and capacitances to a gain of an input to the ADC circuitry 225. The resistors 405, 425 and the capacitors 410, 430 set a gain of signals from the interconnect circuitry 215. The resistors 415, 425 and the capacitors 420, 430 set a gain of signals from the amplifier circuitry 235. In example operations, the resistors 405, 415, 425 are also structured as summing circuitry, which combines currents from the interconnect circuitry 215 and the amplifier circuitry 235. Alternatively, as shown in FIGS. 2 and 3, the resistors 405, 415, 425 and the capacitors 410, 420, 430 may be replaced or illustrated using an amplifier and combination circuitry, such as the combination circuitry 220 of FIGS. 2 and 3 and the amplifier circuitry 245 of FIGS. 2 and 3.

FIG. 5 is a flowchart representative of example operations 500 that may be at least one of executed, instantiated, or performed using an example implementation of the inter-stage gain circuitry 105, 110, 115, 200, 300, 400 of FIGS. 1, 2, 3, and 4. The example operations 500 of FIG. 5 begin at Block 505, at which the inter-stage gain circuitry 105, 110, 115, 200, 300 receives an analog signal. (Block 505). In some examples, such as FIGS. 2 and 4, the inter-stage gain circuitry 200, 400 receives a single-ended analog input signal. In other examples, such as FIG. 3, the inter-stage gain circuitry 300 receives p-side and m-side analog input signals as a differential pair of signals that represent the analog input signal.

The delay circuitry 205, 305 of FIGS. 2, 3, and 4 delays the analog signal. (Block 510). In some examples, the delay circuitry 205, 305 decreases the speed of propagation of the analog signal using a passive component, such as an electrical trace. In other examples, the delay circuitry 205, 305 is a discrete component having a propagation delay, which delays the analog signal. In both examples, the delay of the delay circuitry 205, 305 is determined by timings of the ADC circuitry 225 and the DAC circuitry 230 of FIGS. 2 and 3. For example, when the ADC circuitry 225 and the DAC circuitry 230 have a propagation delay of ten milli-seconds, the delay circuitry 205, 305 is structured to have a delay of approximately ten milli-seconds.

The ADC circuitry 225 samples the analog signal to determine an analog input voltage at a sample time. (Block 515). In some examples, the ADC circuitry 225 samples and holds the analog signal to determine the analog input voltage to be converted to digital. In some such examples, the ADC circuitry 225 periodically samples the analog signal responsive to a clock signal, which determines the sample timing. In some example operations, the resistors 405, 425 of FIG. 4 have resistances that amplify the analog signal by a gain value. In some such examples, the capacitors 410, 430 of FIG. 4 have capacitances to stabilize a timing of the analog signal in relation to feedback from the resistor 415 of FIG. 4 and the capacitor 420 of FIG. 4.

The ADC circuitry 225 converts the analog input voltage into digital bits. (Block 520). In some examples, the ADC circuitry 225 implements an analog-to-digital conversion technique to determine digital bits that represent the analog input voltage. In such examples, the ADC circuitry 225 generates a relatively low-resolution representation of the analog input voltage in comparison to the digital output from the latch 150 of FIG. 1. For example, the ADC circuitry 225 generates a three-bit representation of the analog input voltage and the latch 150 provides a sixteen-bit representation of the analog input voltage. In such examples, additional instances of the inter-stage gain circuitry 105, 110, 115, 200, 300 supply the additional digital bits. Alternatively, in some examples, only the most significant bit (MSB) of the ADC circuitry 225 is supplied to the latch 150. Advantageously, implementing a relatively low-resolution analog-to-digital conversion may increase the conversion speed and decrease the complexity of the ADC circuitry 225.

The DAC circuitry 230 generates an approximate analog voltage using the digital bits. (Block 525). In some examples, the DAC circuitry 230 implements a digital-to-analog conversion technique to generate an analog voltage using the digital bits from the ADC circuitry 225. However, since the digital bits are a relatively low-resolution representation of the analog input voltage, the analog voltage of the DAC circuitry 230 is an approximate representation of the analog input voltage. Also, the DAC circuitry 230 may receive the most significant bits from the ADC circuitry 225 to further decrease a conversion time.

The amplifier circuitry 235 of FIGS. 2 and 3 amplifies the difference between the approximate analog voltage and the delayed analog input signal by a gain. (Block 530). In some examples, the amplifier circuitry 235 receives the analog signal from the resistor 210 of FIG. 2 and the approximate analog voltage from the DAC circuitry 230. In such examples, the amplifier circuitry 235 generates an output based on the difference between the analog input voltage from the delay circuitry 205 and the approximate analog voltage from the DAC circuitry 230. Such a difference between the approximate analog voltage and the analog input voltage is referred to as a residue or quantization error. The residue represents the difference between a relatively low-resolution digital approximation of the analog input voltage and the actual analog input voltage. Also, the amplifier circuitry 235 amplifies the residue by a gain, which is referred to as an inter-stage gain. The inter-stage gain allows subsequent inter-stage gain circuitry (e.g., the inter-stage gain circuitry 110, 115) to use ADC circuitry and DAC circuitry that have the same resolution as the ADC circuitry 225 and the DAC circuitry 230 of the previous stage. Advantageously, such an inter-stage gain reduces complexity when determining relatively higher-precision bits of the analog input voltage.

The filter circuitry 240 of FIGS. 2 and 3 filters the difference between the approximate analog voltage and the delayed analog input signal. (Block 535). In some examples, the filter circuitry 240 is coupled to provide a feedback path between the non-inverting input and the output of the amplifier circuitry 235. In such examples, the filter circuitry 240 improves stability of the inter-stage gain circuitry 200 by limiting the amplifier circuitry 235 response time to changes at the input. Also, the filter circuitry 240 improves the output of the amplifier circuitry 235 by preventing the amplifier circuitry 235 from amplifying relatively high-frequency noise.

The amplifier circuitry 245 of FIGS. 2 and 3 or the resistors 415, 425 determine a residue of the amplified difference. (Block 540). In some examples, the filter circuitry 240 includes a capacitive or inductive component, such as the capacitors 250, 315 of FIGS. 2 and 3. In such examples, the filter circuitry 240 accumulates excess charge from a previous residue. The excess charge from the previous residue depends on the frequency of the inter-stage gain circuitry 200, 300 and the voltage at the output of the amplifier circuitry 235 (V(t)). The amplifier circuitry 245 may use Equation (1), below, to predict the voltage at the output of the amplifier circuitry 235 for the next analog input voltage from the ADC circuitry 225 (V(t+ΔT)) based on the current voltage at the output of the amplifier circuitry 235. In such an example, the amplifier circuitry 245 may use Equation (1), below, to determine a gain that accounts for the residue of a subsequent sample at a subsequent time (t+ΔT). In some examples, the resistors 415, 425 have resistances that set the gain of the feedback from the amplifier circuitry 235 using Equation (1), below.

$${V}_{res} ( t + Δ T ) \approx V ( t ) + \frac{dV ( f )}{dt Δ T} \qquad Equation ( 1 )$$

In other examples, the amplifier circuitry 235 uses the complex domain (also referred to as the frequency domain or s-domain) to predict a subsequent residue Vᵣₑₛ(t+ΔT). In such examples, a Laplace transformation of Equation (1), above, may be used to determine the subsequent residue. Such a Laplace transformation is illustrated by Equation (2), below. Advantageously, in the s-domain, the zeros and poles characterize the gain of the filter circuitry 240. Determining the transfer function (H(s)) of Equation (2), below, simplifies determining the poles and zeros. Equation (3), below, illustrates the transfer function of the inter-stage gain circuitry 200, 300 having an inter-stage gain (Gₐ). However, the capacitive or inductive components of the filter circuitry 240 discharges between samples of the ADC circuitry 225. Multiplying Equation (3) by a decay value (d_{f}) accounts for the remaining residue at the next sample time plus the delay of the delay circuitry 205. The amplifier circuitry 235 may use Equation (4), below, to determine the remaining residue at the subsequent time. Advantageously, Equation (4) allows the amplifier circuitry 235 to determine the remaining residue of the filter circuitry 240 at a future time without needing to integrate or derive the output of the amplifier circuitry 235.

$$Laplace ( {V}_{res} ( t + Δ T ) ) = V ( s ) + s V ( s ) k \qquad Equation ( 2 )$$

$$H ( s ) = \frac{V ( s ) + s V ( s ) k}{V ( s ) + s V ( s ) k \frac{1}{{G}_{a}}} \qquad Equation ( 3 )$$

$${V}_{r e s} ( t + Δ T ) \approx {d}_{f} \times \frac{1 + {k}_{s}}{1 + \frac{ks}{{G}_{a}}} \qquad Equation ( 4 )$$

The combination circuitry 220 of FIGS. 2 and 3 compensates the analog signal for the residue. (Block 545). In some examples, the combination circuitry 220 subtracts the determined residue from the amplifier circuitry 245 from the analog input signal. In such examples, the combination circuitry 220 adjusts the analog input signal to account for the accumulation of charge from the previous residue in the filter circuitry 240. Advantageously, the amplifier circuitry 245 reduces errors resulting from previous residues. Advantageously, the resistors 415, 425 reduce errors resulting from previous residues. Further the capacitors 410, 420, 430 allow the inter-stage gain circuitry 400 to have a gain equal to zero.

The ADC circuitry 225 samples the compensated analog signal to determine the analog input voltage at another sample time. (Block 550). In some examples, the ADC circuitry 225 samples and holds the compensated analog signal to determine the analog input voltage to be converted to digital. In some such examples, the ADC circuitry 225 periodically samples the compensated analog signal to generate subsequent digital values.

Advantageously, the ADC circuitry 225 uses a compensated analog signal to generate the digital bits. Advantageously, the DAC circuitry 230 uses the compensated digital bits to generate a compensated approximate analog voltage. Advantageously, the compensated approximate analog voltage increases the accuracy of the amplifier circuitry 235 by accounting for accumulated charge in the filter circuitry 240 from previous residues.

Although example methods are described with reference to the flowchart illustrated in FIG. 5, many other methods of implementing the inter-stage gain circuitry 105, 110, 115, 200, 300 of FIGS. 1, 2, and 3 and the amplifier circuitry 245 of FIGS. 2 and 3 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

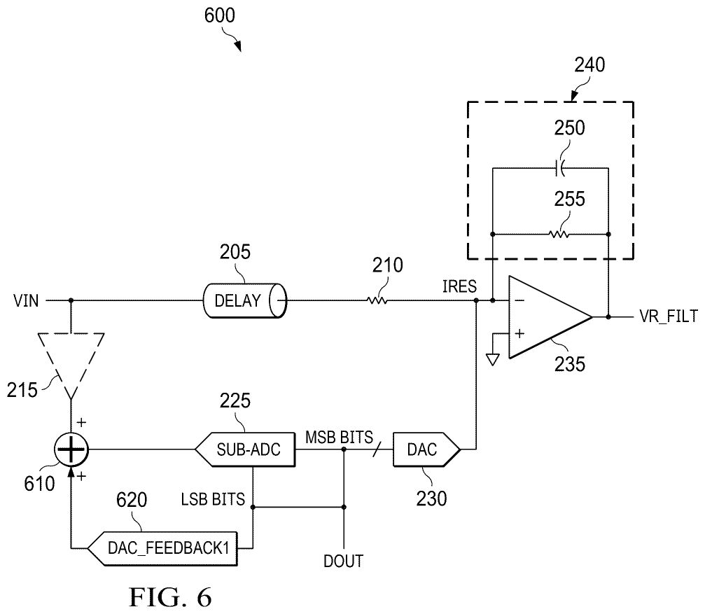

FIG. 6 is a schematic diagram of example inter-stage gain circuitry 600, which is another example of the inter-stage gain circuitry 105, 110, 115, 200, 300 of FIGS. 1, 2, and 3. In the example of FIG. 6, the inter-stage gain circuitry 600 includes the delay circuitry 205 of FIGS. 2 and 3, the resistor 210 of FIGS. 2 and 3, the interconnect circuitry 215 of FIGS. 2 and 3, the ADC circuitry 225 of FIGS. 2 and 3, the DAC circuitry 230 of FIGS. 2 and 3, the amplifier circuitry 235 of FIGS. 2 and 3, the filter circuitry 240 of FIGS. 2 and 3, combination circuitry 610, and second DAC circuitry 620. The example filter circuitry 240 of FIG. 6 includes the capacitor 250 of FIGS. 2 and 3 and the resistor 255 of FIGS. 2 and 3.

The inter-stage gain circuitry 600 has an input terminal, a first output terminal, and a second output terminal. The input terminal of the inter-stage gain circuitry 600 is structured to be coupled to one of an output terminal of a prior instance of the inter-stage gain circuitry 600 or external circuitry, which supplies an analog input signal (Vin). In both examples, the inter-stage gain circuitry 600 receives the analog input signal at the input terminal. The first output terminal of the inter-stage gain circuitry 600 is structured to be coupled to a subsequent instance of the inter-stage gain circuitry 600. The second output terminal of the inter-stage gain circuitry 600 is structured to be coupled to a latch (e.g., the latches 120, 130, 140 of FIG. 1). In some examples, the inter-stage gain circuitry 600 has a plurality of output terminals that are structured to supply a plurality of digital bits to a latch or external circuitry.

The combination circuitry 610 has a first terminal, a second terminal, and a third terminal. The first terminal of the combination circuitry 610 (also referred to as a first input terminal) is coupled to the interconnect circuitry 215. The second terminal of the combination circuitry 610 (also referred to as a second input terminal) is coupled to the DAC circuitry 620. The third terminal of the combination circuitry 610 (also referred to as an output terminal) is coupled to the ADC circuitry 225. In the example of FIG. 6, the combination circuitry 610 is structured as addition circuitry, which generates an output voltage by adding the voltages of the inputs.

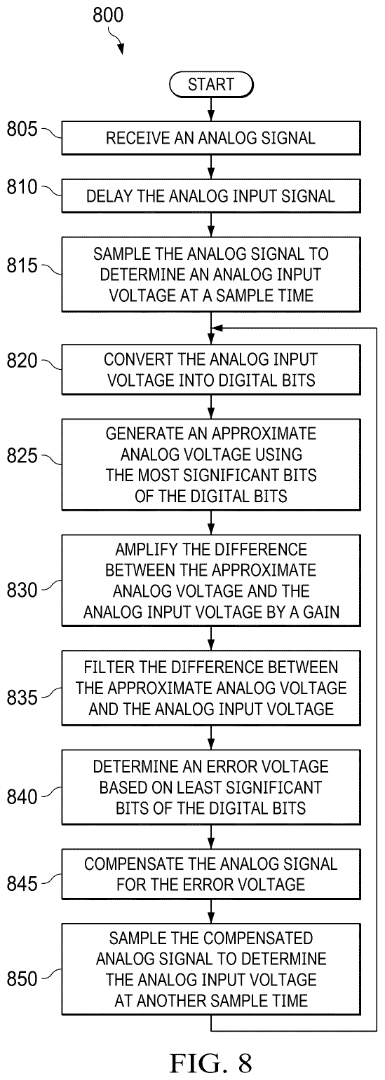

The DAC circuitry 620 (also referred to as feedback circuitry) has an input terminal and an output terminal. The input terminal of the DAC circuitry 620 is coupled to the ADC circuitry 225. The output terminal of the DAC circuitry 620 is coupled to the combination circuitry 610. In the example of FIG. 6, the DAC circuitry 620 is structured to receive one or more of the least significant bits (LSBs) of the output of the ADC circuitry 225. For example, when the ADC circuitry 225 performs a six-bit analog-to-digital conversion, the ADC circuitry 225 supplies the three most significant bits to the DAC circuitry 230 and the three least significant bits to the DAC circuitry 620. Advantageously, the three least significant bits represent the quantization error between the approximate analog voltage from the DAC circuitry 230 and the actual value of analog input voltage. Example operations of the inter-stage gain circuitry 600 are illustrated and described in connection with FIG. 8, below.

FIG. 7 is a schematic diagram of example inter-stage gain circuitry 700, which is another example of the inter-stage gain circuitry 105, 110, 115, 200, 300, 600 of FIGS. 1, 2, 3, and 5. In the example of FIG. 7, the inter-stage gain circuitry 700 includes the delay circuitry 205 of FIGS. 2, 3, and 4, the resistor 210 of FIGS. 2, 3, and 4, the interconnect circuitry 215 of FIGS. 2, 3, and 4, the ADC circuitry 225 of FIGS. 2, 3, and 4, the DAC circuitry 230 of FIGS. 2, 3, and 4, the amplifier circuitry 235 of FIGS. 2, 3, and 4, combination circuitry 705, second DAC circuitry 710, second delay circuitry 715, third DAC circuitry 720, and filter circuitry 725. The example filter circuitry 725 of FIG. 7 includes a first example capacitor 730, a second example resistor 735, a third example resistor 740, a second example capacitor 745, a fourth example resistor 750, third example amplifier circuitry 755, a fifth example resistor 760, and a third example capacitor 765.

The inter-stage gain circuitry 700 has an input terminal, a first output terminal, and a second output terminal. The input terminal of the inter-stage gain circuitry 700 is structured to be coupled to one of an output terminal of a prior instance of the inter-stage gain circuitry 700 or external circuitry, which supplies an analog input signal (Vin). In both examples, the inter-stage gain circuitry 700 receives the analog input signal at the input terminal. The first output terminal of the inter-stage gain circuitry 700 is structured to be coupled to a subsequent instance of the inter-stage gain circuitry 700. The second output terminal of the inter-stage gain circuitry 700 is structured to be coupled to a latch (e.g., the latches 120, 130, 140 of FIG. 1). In some examples, the inter-stage gain circuitry 700 has a plurality of output terminals that are structured to supply a plurality of digital bits to a latch or external circuitry.

The combination circuitry 705 has a first terminal, a second terminal, a third terminal, and a fourth terminal. The first terminal of the combination circuitry 705 (also referred to as a first input terminal) is coupled to the interconnect circuitry 215. The second terminal of the combination circuitry 705 (also referred to as a second input terminal) is coupled to the DAC circuitry 710. The third terminal of the combination circuitry 705 (also referred to as a third input terminal) is coupled to the DAC circuitry 720. The fourth terminal of the combination circuitry 705 (also referred to as an output terminal) is coupled to the ADC circuitry 225. In the example of FIG. 7, the combination circuitry 705 is structured as addition circuitry, which generates an output voltage by adding the voltages of the inputs.

The DAC circuitry 710 has an input terminal and an output terminal. The input terminal of the DAC circuitry 710 is coupled to the ADC circuitry 225. The output terminal of the DAC circuitry 710 is coupled to the combination circuitry 705. The delay circuitry 715 has an input terminal and an output terminal. The input terminal of the delay circuitry 715 is coupled to the ADC circuitry 225 and the DAC circuitry 710. The output terminal of the delay circuitry 715 is coupled to the DAC circuitry 720. The DAC circuitry 720 has an input terminal and an output terminal. The input terminal of the DAC circuitry 720 is coupled to the delay circuitry 715. The output terminal of the DAC circuitry 720 is coupled to the combination circuitry 705. The DAC circuitry 710, 720 and the delay circuitry 715 may be referred to as feedback circuitry.

In the example of FIG. 7, the DAC circuitry 710 and the delay circuitry 715 are structured to receive one or more of the least significant bits (LSBs) of the output of the ADC circuitry 225. For example, when the ADC circuitry 225 performs a six-bit analog-to-digital conversion, the ADC circuitry 225 supplies the three most significant bits to the DAC circuitry 230 and the three least significant bits to the DAC circuitry 710 and the delay circuitry 715. Advantageously, the three least significant bits represent the quantization error between the approximate analog voltage from the DAC circuitry 230 and the actual value of analog input voltage.

The filter circuitry 725 has a first terminal, a second terminal, and a third terminal. The first terminal of the filter circuitry 725 is coupled to the resistor 210, the DAC circuitry 230, and the amplifier circuitry 235. The second terminal of the filter circuitry 725 is coupled to the amplifier circuitry 235. The third terminal of the filter circuitry 725 is coupled to the first output terminal of the inter-stage gain circuitry 700, which may be coupled to another instance of the inter-stage gain circuitry 700.

The capacitor 730 has a first terminal and a second terminal. The first terminal of the capacitor 730 is coupled to the resistors 210, 735, the DAC circuitry 230, and the amplifier circuitry 235. The second terminal of the capacitor 730 is coupled to the amplifier circuitry 235 and the resistors 735, 740. The resistor 735 has a first terminal and a second terminal. The first terminal of the resistor 735 is coupled to the resistor 210, the DAC circuitry 230, the amplifier circuitry 235, and the capacitor 730. The second terminal of the resistor 735 is coupled to the amplifier circuitry 235, the capacitor 730, and the resistor 740.

The resistor 740 has a first terminal and a second terminal. The first terminal of the resistor 740 is coupled to the amplifier circuitry 235, the capacitor 730, and the resistor 735. The second terminal of the resistor 740 is coupled to the capacitor 745 and the resistor 750. The capacitor 745 has a first terminal and a second terminal. The first terminal of the capacitor 745 is coupled to the resistors 740, 750. The second terminal of the capacitor 745 is coupled to the common terminal, which supplies the common potential. The resistor 750 has a first terminal and a second terminal. The first terminal of the resistor 750 is coupled to the resistor 740 and the capacitor 745. The second terminal of the resistor 750 is coupled to the amplifier circuitry 755, the resistor 760, and the capacitor 765.

The amplifier circuitry 755 has a first input terminal, a second input terminal, and an output terminal. The first input terminal of the amplifier circuitry 755 (also referred to as an inverting input) is coupled to the resistors 750, 760 and the capacitor 765. The second input terminal of the amplifier circuitry 755 (also referred to as a non-inverting input terminal) is coupled to the common terminal, which supplies the common potential. The output terminal of the amplifier circuitry 755 is coupled to the resistor 760, the capacitor 765, and the first output terminal of the inter-stage gain circuitry 700, which may be coupled to a subsequent instance of the inter-stage gain circuitry 700.

The resistor 760 has a first terminal and a second terminal. The first terminal of the resistor 760 is coupled to the resistor 750, the amplifier circuitry 755, and the capacitor 765. The second terminal of the resistor 760 is coupled to the amplifier circuitry 755, the capacitor 765, and the first output terminal of the inter-stage gain circuitry 700, which may be coupled to a subsequent instance of the inter-stage gain circuitry 700. The capacitor 765 has a first terminal and a second terminal. The first terminal of the capacitor 765 is coupled to the resistors 750, 760 and the amplifier circuitry 755. The second terminal of the capacitor 765 is coupled to the amplifier circuitry 755, the resistor 760, and the first output terminal of the inter-stage gain circuitry 700, which may be coupled to a subsequent instance of the inter-stage gain circuitry 700.

In the example of FIG. 7, the filter circuitry 725 is a relatively high order filter in comparison to the filter circuitry 240. Alternatively, the filter circuitry 725 may be replaced with alternative circuitry to form a different order of filter or another type of filter. Advantageously, higher order filters reduce errors at the output of the inter-stage gain circuitry 700. Example operations of the inter-stage gain circuitry 700 are illustrated and described in connection with FIG. 8, below.

FIG. 8 is a flowchart representative of example operations 800 that may be at least one of executed, instantiated, or performed using an example implementation of the inter-stage gain circuitry 105, 110, 115, 600, 700 of FIGS. 1, 5, and 6. The example operations 800 of FIG. 8 begin at Block 805, at which the inter-stage gain circuitry 105, 110, 115, 600, 700 receives an analog signal. (Block 805). In some examples, the inter-stage gain circuitry 600, 700 receives a single-ended analog input signal. Alternatively, similar to the modifications of FIG. 3, the inter-stage gain circuitry 600, 700 may be modified to receive p-side and m-side analog input signals as a differential pair of signals that represent the analog input signal.

The delay circuitry 205 of FIGS. 2, 3, 5, and 6 delays the analog signal. (Block 810). In some examples, the delay circuitry 205 decreases the speed of propagation of the analog signal using a passive component, such as an electrical trace. In other examples, the delay circuitry 205 is a discrete component having a propagation delay, which delays the analog signal. In both examples, the delay of the delay circuitry 205 is determined by timings of the ADC circuitry 225 and the DAC circuitry 230 of FIGS. 2, 3, 5, and 6. For example, when the ADC circuitry 225 and the DAC circuitry 230 have a propagation delay of ten milli-seconds, the delay circuitry 205 is structured to have a delay of approximately ten milli-seconds.

The ADC circuitry 225 samples the analog signal to determine an analog input voltage at a sample time. (Block 815). In some examples, the ADC circuitry 225 samples and holds the analog signal to determine the analog input voltage to be converted to digital. In some such examples, the ADC circuitry 225 periodically samples the analog signal responsive to a clock signal, which determines the sample timing.

The ADC circuitry 225 converts the analog input voltage into digital bits. (Block 820). In some examples, the ADC circuitry 225 implements an analog-to-digital conversion technique to determine digital bits that represent the analog input voltage. In such examples, the ADC circuitry 225 generates a low-resolution representation of the analog input voltage in comparison to the digital output from the latch 150 of FIG. 1. For example, the ADC circuitry 225 generates a three-bit representation of the analog input voltage and the latch 150 provides a sixteen-bit representation of the analog input voltage. In such examples, additional instances of the inter-stage gain circuitry 105, 110, 115, 600, 700 supply the additional digital bits. Alternatively, in some examples, only the most significant bit (MSB) of the ADC circuitry 225 is supplied to the latch 150. Advantageously, implementing a low-resolution analog-to-digital conversion may increase the conversion speed and decrease the complexity of the ADC circuitry 225.

The DAC circuitry 230 generates an approximate analog voltage using the most significant bits of the digital bits. (Block 825). In some examples, the DAC circuitry 230 implements a digital-to-analog conversion technique to generate an analog voltage using the digital bits from the ADC circuitry 225. However, since the digital bits are a low-resolution representation of the analog input voltage, the analog voltage of the DAC circuitry 230 is an approximate representation of the analog input voltage. In some such examples, the DAC circuitry 230 may use one or more of the most significant bits of the digital bits to generate the approximate analog voltage. Advantageously, reducing the number of bits that the DAC circuitry 230 converts to analog increases a speed of the digital-to-analog conversion.

The amplifier circuitry 235 of FIGS. 2 and 3 amplifies the difference between the approximate analog voltage and the delayed analog input signal by a gain. (Block 830). In some examples, the amplifier circuitry 235 receives the analog signal from the resistor 210 of FIGS. 2, 3, 6, and 7 and the approximate analog voltage from the DAC circuitry 230 at a non-inverting input. In such examples, the amplifier circuitry 235 generates an output based on the difference between the analog input voltage from the delay circuitry 205 and the approximate analog voltage from the DAC circuitry 230. Such a difference between the approximate analog voltage and the analog input voltage is referred to as a residue. The residue represents the difference between a low-resolution digital approximation of the analog input voltage and the actual analog input voltage. In some examples, the residue is referred to or described in relation to a quantization error. Also, the amplifier circuitry 235 amplifies the residue by a gain, which is referred to as an inter-stage gain. The inter-stage gain allows subsequent inter-stage gain circuitry (e.g., the inter-stage gain circuitry 110, 115) to use ADC circuitry and DAC circuitry that have the same resolution as the ADC circuitry 225 and the DAC circuitry 230 of the previous stage. Advantageously, such an inter-stage gain reduces complexity when determining higher-precision bits of the analog input voltage.

The filter circuitry 240, 725 of FIGS. 2, 3, 6, and 7 filters the difference between the approximate analog voltage and the delayed analog input signal. (Block 835). In some examples, the filter circuitry 240, 725 are coupled to provide a feedback path between the non-inverting input and the output of the amplifier circuitry 235. In such examples, the filter circuitry 240, 725 improves stability of the inter-stage gain circuitry 600, 700 by limiting the amplifier circuitry 235 response time to changes at the input. Also, the filter circuitry 240, 725 improve the output of the amplifier circuitry 235 by preventing the amplifier circuitry 235 from amplifying high-frequency noise.

The DAC circuitry 620, 710, 720 of FIGS. 6 and 7 determine an error voltage based on least significant bits of the digital bits. (Block 840). In some examples, the DAC circuitry 620, 710 generate an error voltage using the least significant bits of the output of the ADC circuitry 225. For example, when the ADC circuitry 225 is a six-bit converter, the DAC circuitry 620, 710 may receive the three least significant bits. The DAC circuitry 620, 710 generates the error voltage as an analog value representing the digital bits. Advantageously, not using the least significant bits to generate the approximate analog voltage sets the error voltage proportional to the residue.

Also, in the example of FIG. 7, the DAC circuitry 720 generates a second error voltage using the least significant bits of a previous output of the ADC circuitry 225. In such examples, the delay circuitry 715 stores or delays supplying the previous least significant bits to the DAC circuitry 720. Advantageously, the delay circuitry 715 and the DAC circuitry 720 allow the inter-stage gain circuitry 700 to account for residue errors across a plurality of samples. Advantageously, the delay circuitry 715 and the DAC circuitry 720 allow the inter-stage gain circuitry 700 to account for residues of relatively high order filters, such as the filter circuitry 725. Advantageously, the least significant bits of the digital bits are an approximate representation of the difference between the approximate analog voltage and the analog input voltage, which approximates the residue.

The combination circuitry 610, 705 of FIGS. 6 and 7 compensates the analog signal for the error voltage. (Block 845). In some examples, the combination circuitry 610, 705 adds the error voltage from the DAC circuitry 620, 710, 720 to the analog signal. In such examples, the combination circuitry 610, 705 compensates the analog signal for the residue of previous samples by adding the error voltages to the analog input signal.

The ADC circuitry 225 samples the compensated analog signal to determine the analog input voltage at another sample time. (Block 850). In some examples, the ADC circuitry 225 samples and holds the compensated analog signal to determine the analog input voltage to be converted to digital. In some such examples, the ADC circuitry 225 periodically samples the compensated analog signal to generate subsequent digital values.

Advantageously, the ADC circuitry 225 uses a compensated analog signal to generate the digital bits. Advantageously, the DAC circuitry 230 uses the compensated digital bits to generate a compensated approximate analog voltage. Advantageously, the compensated approximate analog voltage increases the accuracy of the amplifier circuitry 235 by accounting for charge accumulation in the filter circuitry 240, 725 from previous residues.

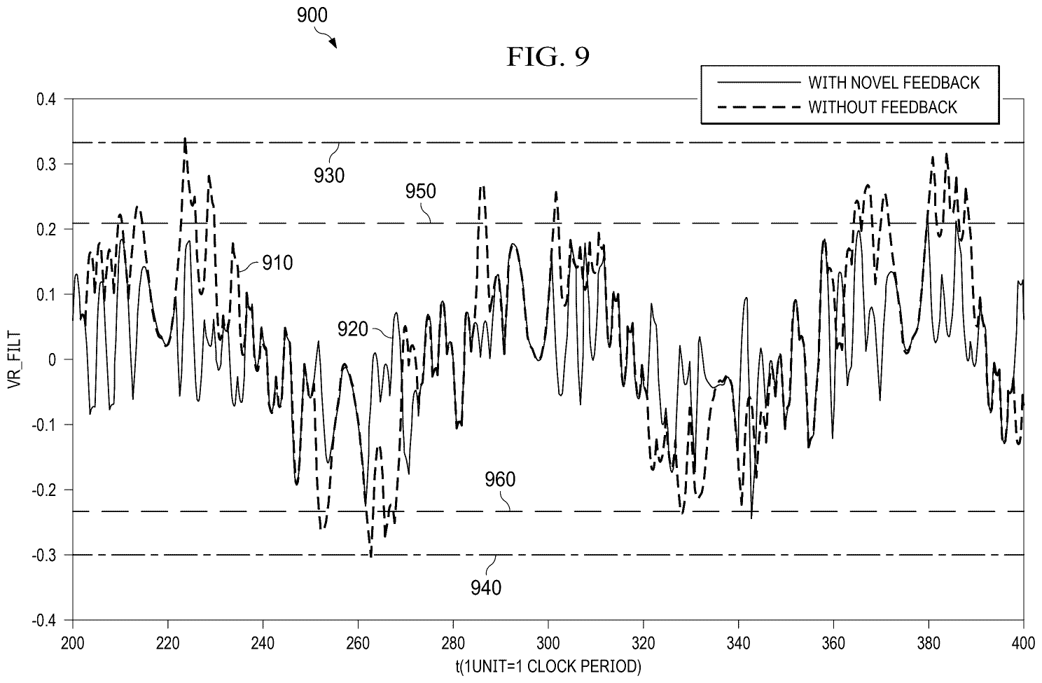

Although example methods are described with reference to the flowchart illustrated in FIG. 9, many other methods of implementing the inter-stage gain circuitry 105, 110, 115, 600, 700 of FIGS. 1, 5, and 6 and the DAC circuitry 620, 710, 720 of FIGS. 5 and 6 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 9 is a timing diagram 900 of example operations of the inter-stage gain circuitry 105, 110, 115, 200, 300, 600, 700 of FIGS. 1, 2, 3, 6, and 7 or more generally the CTP ADC circuitry 100 of FIG. 1. In the example of FIG. 9, the timing diagram 900 includes a reference output voltage 910 and a compensated output voltage 920. The reference output voltage 910 illustrates an output of the amplifier circuitry 235 of FIGS. 2, 3, 6, and 7 when the amplifier circuitry 245 of FIGS. 2 and 3 and the DAC circuitry 620, 710, 720 of FIGS. 6 and 7 are not enabled (e.g., turned off, not operating, etc.) over time. The reference output voltage 910 has amplitudes ranging from a first voltage 930 to a second voltage 940. The compensated output voltage 920 illustrates an output of the amplifier circuitry 235 when the amplifier circuitry 245 or the DAC circuitry 620, 710, 720 are enabled (e.g., turned on, operating, etc.) over time. The compensated output voltage 920 has amplitudes ranging from a third voltage 950 to a fourth voltage 960. Advantageously, using feedback from the amplifier circuitry 245 or the DAC circuitry 620, 710, 720 to compensate the analog input signal decreases variations at the output of the inter-stage gain circuitry 105, 110, 115, 200, 300, 600, 700.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

What is claimed is:

1. An apparatus comprising:
combination circuitry having a first input, a second input, and an output;
analog-to-digital converter (ADC) circuitry having an input and an output, the input of the ADC circuitry coupled to the output of the combination circuitry;
digital-to-analog converter (DAC) circuitry having an input and an output, the input of the DAC coupled to the output of the ADC circuitry;
a resistor having a first terminal and a second terminal, the first terminal of the resistor coupled to the first input of the combination circuitry;
amplifier circuitry having an input coupled to the output of the DAC circuitry and the second terminal of the resistor.

2. The apparatus of claim 1, wherein the amplifier circuitry is first amplifier circuitry, the first amplifier circuitry further has an output, and the apparatus further comprises second amplifier circuitry having an input and an output, wherein the input of the second amplifier circuitry is coupled to the output of the first amplifier circuitry, and the output of the second amplifier circuitry is coupled to the second input of the combination circuitry.

3. The apparatus of claim 1, wherein the DAC circuitry is first DAC circuitry, the output of the ADC circuitry is a first output, the ADC circuitry further has a second output, and the apparatus further comprises second DAC circuitry having an input and an output, the input of the second DAC circuitry is coupled to the second output of the ADC circuitry, and the output of the second DAC circuitry is coupled to the second input of the combination circuitry.

4. The apparatus of claim 1, wherein the amplifier circuitry further has an output, and the apparatus further comprising inter-stage gain circuitry having an input coupled to the output of the amplifier circuitry.

5. The apparatus of claim 1, wherein the amplifier circuitry further has an output, and the apparatus further comprises:
delay circuitry having a first terminal and a second terminal, the first terminal of the delay circuitry coupled to the first input of the combination circuitry and the second terminal of the delay circuitry coupled to the first terminal of the resistor; and
filter circuitry having a first terminal and a second terminal, the first terminal of the filter circuitry is coupled to the output of the DAC circuitry, the second terminal of the resistor, and the input of the amplifier circuitry, the second terminal of the filter circuitry is coupled to the output of the amplifier circuitry.

6. An apparatus comprising:
combination circuitry having an input and an output;
analog-to-digital converter (ADC) circuitry having an input and an output, the input of the ADC circuitry coupled to the output of the combination circuitry;
digital-to-analog converter (DAC) circuitry having an input and an output, the input of the DAC coupled to the output of the ADC circuitry;
first amplifier circuitry having an input and an output, the input of the first amplifier circuitry coupled to the output of the DAC circuitry; and
second amplifier circuitry having an input and an output, the input of the second amplifier circuitry coupled to the output of the first amplifier circuitry, the output of the second amplifier circuitry coupled to the input of the combination circuitry.

7. The apparatus of claim 6, wherein the input of the combination circuitry is a first input, the combination circuitry further having a second input, and the apparatus further comprises:
delay circuitry having a first terminal and a second terminal, the first terminal of the delay circuitry is coupled to the second input of the combination circuitry; and
a resistor having a first terminal and a second terminal, the first terminal of the resistor is coupled to the second terminal of the delay circuitry, the second terminal of the resistor is coupled to the output of the DAC circuitry and the input of the first amplifier circuitry.

8. The apparatus of claim 6, wherein the combination circuitry is subtraction circuitry.

9. The apparatus of claim 6, further comprises:
inter-stage gain circuitry having an input coupled to the output of the first amplifier circuitry and the input of the second amplifier circuitry; and
a latch having an input coupled to the output of the ADC circuitry and the input of the DAC circuitry.

10. The apparatus of claim 6, further comprising filter circuitry including:
a capacitor having a first terminal and a second terminal; and
a resistor having a first terminal and a second terminal, the first terminal of the resistor is coupled to the output terminal of the DAC circuitry, the input of the first amplifier circuitry, and the first terminal of the capacitor, the second terminal of the resistor is coupled to the output of the first amplifier circuitry, the input of the second amplifier circuitry, and the second terminal of the capacitor.

11. An apparatus comprising:
combination circuitry having an input and an output;
analog-to-digital converter (ADC) circuitry having an input, a first output, and a second output, the input of the ADC circuitry coupled to the output of the combination circuitry;
first digital-to-analog converter (DAC) circuitry having an input and an output, the input of the first DAC coupled to the first output of the ADC circuitry;
amplifier circuitry having an input coupled to the output of the DAC circuitry; and
second DAC circuitry having an input and an output, the input of the second DAC coupled to the second output of the ADC circuitry, the output of the second DAC coupled to the input of the combination circuitry.

12. The apparatus of claim 11, wherein the input of the combination circuitry is a first input, the combination circuitry further having a second input, and the apparatus further comprises:
delay circuitry having a first terminal and a second terminal, the first terminal of the delay circuitry is coupled to the second input of the combination circuitry; and
a resistor having a first terminal and a second terminal, the first terminal of the resistor is coupled to the second terminal of the delay circuitry, the second terminal of the resistor is coupled to the output of the first DAC circuitry and the input of the amplifier circuitry.

13. The apparatus of claim 11, wherein the combination circuitry is addition circuitry.

14. The apparatus of claim 11, wherein the amplifier circuitry further has an output terminal, and the apparatus further comprises:
inter-stage gain circuitry having an input coupled to the output of the amplifier circuitry; and
a latch having an input coupled to the output of the ADC circuitry and the input of the first DAC circuitry.

15. The apparatus of claim 11, wherein the amplifier circuitry further has an output terminal, further comprising filter circuitry includes:
a capacitor having a first terminal and a second terminal; and
a resistor having a first terminal and a second terminal, the first terminal of the resistor is coupled to the output of the DAC circuitry, the input of the amplifier circuitry, and the first terminal of the capacitor, the second terminal of the resistor is coupled to the output of the amplifier circuitry and the second terminal of the capacitor.

16. An apparatus comprising:
first inter-stage gain circuitry including:
combination circuitry having an input and an output;
analog-to-digital converter (ADC) circuitry having an input and an output, the input of the ADC circuitry coupled to the output of the combination circuitry;
digital-to-analog converter (DAC) circuitry having an input and an output, the input of the DAC coupled to the output of the ADC circuitry; and
amplifier circuitry having an input and an output, the input of the amplifier circuitry coupled to the output of the DAC circuitry; and
second inter-stage gain circuitry having an input coupled to the output of the amplifier circuitry.

17. The apparatus of claim 16, wherein the amplifier circuitry is first amplifier circuitry, the first amplifier circuitry further has an output, and the apparatus further comprises second amplifier circuitry having an input coupled to the output of the first amplifier circuitry and the input of the second inter-stage gain circuitry.

18. The apparatus of claim 16, wherein the DAC circuitry is first DAC circuitry, the output of the ADC circuitry is a first output, the ADC circuitry further has a second output, and the apparatus further comprises second DAC circuitry having an input coupled to the second output of the ADC circuitry.

19. The apparatus of claim 16, wherein the input of the combination circuitry is a first input, the combination circuitry further having a second input, and the apparatus further comprises:
delay circuitry having a first terminal and a second terminal, the first terminal of the delay circuitry is coupled to the second input of the combination circuitry; and
a resistor having a first terminal and a second terminal, the first terminal of the resistor is coupled to the second terminal of the delay circuitry, the second terminal of the resistor is coupled to the output of the DAC circuitry and the input of the amplifier circuitry.

20. The apparatus of claim 16, further comprises filter circuitry including:
a capacitor having a first terminal and a second terminal; and
a resistor having a first terminal and a second terminal, the first terminal of the resistor is coupled to the output of the DAC circuitry, the input of the amplifier circuitry, and the first terminal of the capacitor, the second terminal of the resistor is coupled to the output of the amplifier circuitry, the input of the second inter-stage gain circuitry, and the second terminal of the capacitor.
